(19) United States
(12) Patent Application Publication
(10) Pub. No.: US 2007/0139057 A1
(43) Pub. Date: Jun. 21, 2007

(54) System and method for radio frequency identification tag direct connection test

(75) Inventors: Danny Nguyen, Centereach, NY (US); Mark Duron, East Patchogue, NY (US); Francisco Naranjo, Brentwood, NY (US); David Reed, Holbrook, NY (US); Gary Seims, East Setauket, NY (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Symbol Technologies, Inc., Holtsville, NY (US)

(21) Appl. No.: 11/300,382

(22) Filed: Dec. 15, 2005

(51) Int. Cl. G01R 27/02; G08B 13/14; G01R 31/26

(52) U.S. Cl. 324/602; 324/765; 340/572.1

(57) ABSTRACT

Methods, systems, and apparatuses for testing radio frequency identification (RFID) tags are described. The tags are tested using a direct connection scheme, where a testing apparatus makes direct contact with a portion of a tag in order to perform a test on the tag. For example, the testing apparatus may read data from the tag to verify operation. Any number of tags may be tested at a time, including one tag at a time, or multiple tags in parallel.

### BACKGROUND OF THE INVENTION

1. Field of the Invention

The present invention relates to the testing of radio frequency identification (RFID) tag devices.

2. Background Art

Radio frequency identification (RFID) tags are electronic devices that may be affixed to items whose presence is to be detected and/or monitored. The presence of an RFID tag, and therefore the presence of the item to which the tag is affixed, may be checked and monitored by devices known as “readers.” Readers typically transmit radio frequency signals to which the tags respond. Each tag can store a unique identification number. The tags respond to the reader transmitted signals by providing their identification number, bit-by-bit, so that they can be identified.

Ideally, tags are tested for proper performance prior to being sold. Demand for RFID tags is estimated to be for over a billion tags a year. Having an accurate high-speed test system that can support such volume is extremely critical. Currently, a test system which can rapidly and reliably handle large volumes of tags does not exist. Current testing systems, which radiate test signals through the air, are extremely difficult to control and are reaching their limits in terms of the volume of tags that can be reliably tested.

Such systems can suffer from a variety of problems. For example, systems using radiated test signals sometimes unintentionally read adjacent tags, and thus have difficulty identifying a specific “bad” tag from a group of tags. Such systems may suffer from interference with the surrounding environment (e.g., interference with other radio frequency signals). When multiple antennas are used, such systems may suffer from cross-talk with the adjacent systems. Furthermore, such systems have difficulties testing multiple tags simultaneously because of the need for a transmitted test signal for each tag under test.

Thus, what is needed is a RFID tag testing scheme which can handle very large volumes of tags, and can test the tags rapidly, in a reliable and repeatable fashion.

### BRIEF SUMMARY OF THE INVENTION

Methods, systems, and apparatuses for testing radio frequency identification (RFID) tags are described. According to embodiments, tags are tested using a direct connection scheme, where a testing apparatus makes direct contact with a portion of a tag in order to perform a test on the tag. For example, the testing apparatus may contact the tag to read data from the tag to verify operation. The methods, systems, and apparatuses described herein may be used to test any number of tags, including one tag at a time, or multiple tags in parallel.

In an embodiment of the present invention, tags are tested. A tag is received that has an antenna formed on a substrate. A test probe is physically contacted to the antenna. A test of the tag is conducted through the test probe.

In another embodiment, tags are tested. A tag is received having an antenna formed on a substrate, and an integrated circuit on the substrate electrically coupled to the antenna. A test probe is physically contacted to the antenna. One or more test signals are conducted through the test probe to the antenna. A response signal (including one or more responses) is received from the antenna through the test probe, the response signal being generated by the integrated circuit. The response signal is analyzed.

In another embodiment of the present invention, a system for testing a plurality of radio frequency identification (RFID) tags is described. A plurality of probe assemblies each include a probe. A test controller is electrically coupled to each of the probe assemblies. The probe of each of the probe assemblies is physically contacted to a corresponding antenna of a respective tag, and conducts one or more test signals from the test controller to the corresponding antenna. A response signal is received through the probes from each of the antennas. The test controller analyzes the response signals received through the probes.

In a further embodiment, a plurality of test controllers may be present, each testing a corresponding tag with a corresponding probe.

In still a further embodiment, each tag may have multiple antennas. A single test probe may be moved among the multiple antennas of each tag to test each tag. Alternatively, multiple test probes may be used to simultaneously test the multiple antennas of each tag.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a plan view of an example radio frequency identification (RFID) tag.

FIG. 2 shows a plan view of an example web of tags that is a continuous roll type.

FIG. 3 shows an example block diagram of a direct contact test system, according to an embodiment of the present invention.

FIGS. 4 and 5 show views of a probe assembly interacting with a tag, according to an example embodiment of the present invention.

FIGS. 6 and 7 show views of a multi-probe probe assembly interacting with a tag, according to an embodiment of the present invention.

FIGS. 8-10 show multi-tag direct connect test systems, according to embodiments of the present invention.

FIGS. 11 and 12 show example direct connect test systems incorporated into tag assembly lines, according to embodiments of the present invention.

FIG. 13 shows a flowchart providing a process for testing tags according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

Introduction

The present invention relates to the testing of radio frequency identification (RFID) tags. According to embodiments of the present invention, tags are tested by a direct connection to the tag. For example, a probe assembly including one or more probes is coupled to the antenna(s) of a tag under test, to test the tag. Such a probe assembly can be used to test tags one-by-one in a serial fashion, moving from tag-to-tag (i.e., moving the probe with respect to the tags, moving the tags with respect to the probe assembly, or both). In further embodiments, multiple probe assemblies can be present to test multiple tags in parallel, if desired. In this manner, very large numbers of tags can be tested in parallel.

It is noted that references in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

### Direct Connection Test Embodiments

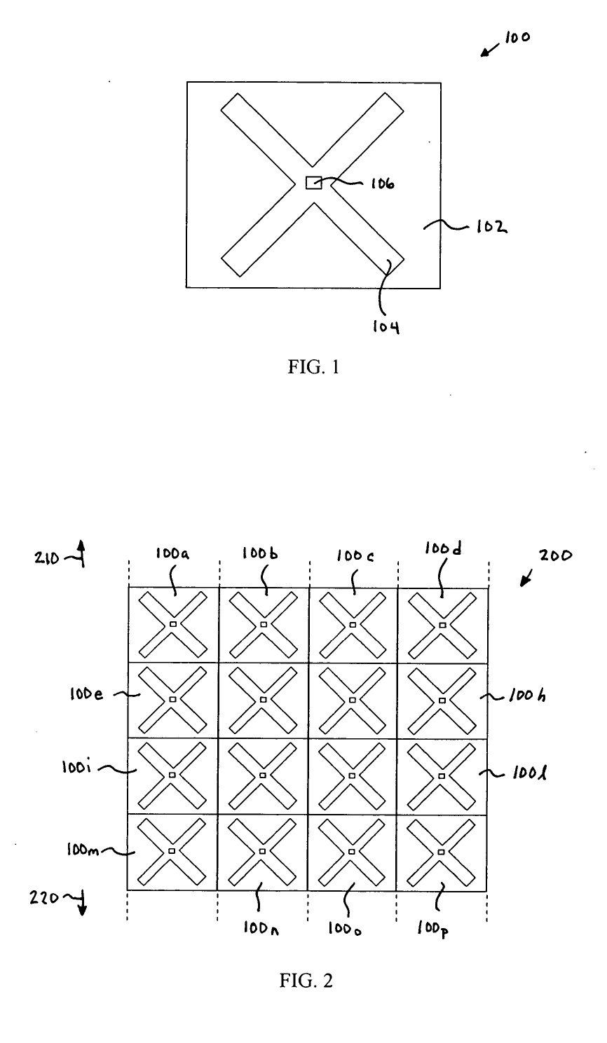

The present invention is applicable to any type of RFID tag. FIG. 1 shows a plan view of an example radio frequency identification (RFID) tag 100. Tag 100 includes a substrate 102, an antenna 104, and an integrated circuit (IC) 106. Antenna 104 is formed on a surface of substrate 102. Antenna 104 may include any number of one or more separate antennas. IC 106 includes one or more integrated circuit chips/dies, and can include other electronic circuitry. IC 106 is attached to substrate 102, and is coupled to antenna 104. IC 106 may be attached to substrate 102 in a recessed and/or non-recessed location. IC 106 controls operation of tag 100, and transmits signals to, and receives signals from RFID readers using antenna 104. Tag 100 may additionally include further elements, including an impedance matching network and/or other circuitry. The present invention is applicable to tag 100, and to other types of tags, including surface wave acoustic (SAW) type tags.

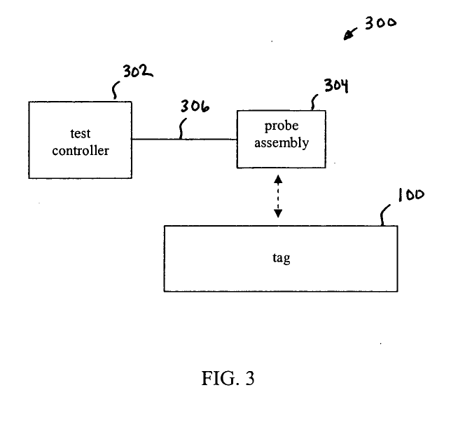

Volume production of RFID tags, such as tag 100, is typically accomplished on a printing web based system. For example, in such a system, the tags are assembled in a web of substrates, which may be a sheet of substrates, a continuous roll of substrates, or other group of substrates. For instance, FIG. 2 shows a plan view of an example web 200 that is a continuous roll type. As shown in FIG. 2, web 200 may extend further in the directions indicated by arrows 210 and 220. Web 200 includes a plurality of tags 100a-p. In the example of FIG. 2, the plurality of tags 100a-p in web 200 is arranged in a plurality of rows and columns. The present invention is applicable to any number of rows and columns of tags, and to other arrangements of tags.

On a web, such as web 200, RFID tags are typically assembled/positioned as close to each other as possible to maximize throughput, thus making the process of reading and testing individual tags difficult. Because of the close spacing, it is very difficult to localize a radiated (e.g., radio frequency) reader field to excite only one tag.

According to embodiments of the present invention, a direct connect test configuration is used to test tags, including tags positioned in close quarters, in a more reliable and repeatable fashion than in conventional tag testing schemes. In embodiments of the present invention, a direct connect test scheme delivers a test signal, such as a radio frequency (RF) test signal, directly to the antenna of an intended tag by making a physical connection.

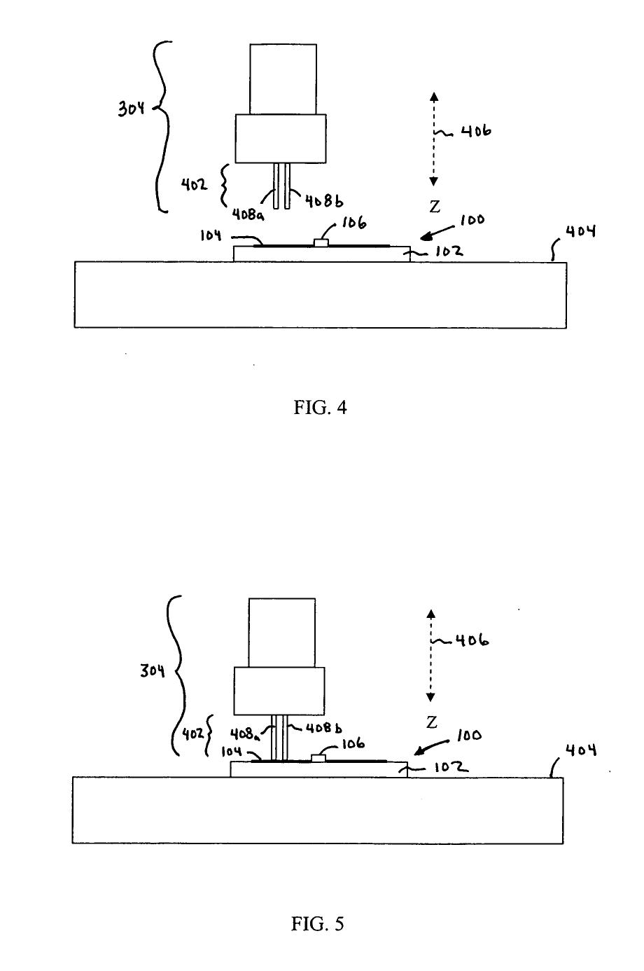

For example, FIG. 3 shows an example block diagram of a direct contact test system 300, according to an embodiment of the present invention. Test system 300 includes a test controller 302 and a probe assembly 304. As shown in FIG. 3, test controller 302 is coupled to probe assembly 304 by a communication link 306 (e.g., wired or wireless). Test controller 302 provides test signals, such as RF test signals, to probe assembly 304 for testing of a tag 100. Probe assembly 304 includes one or more probes for making contact with one or more antennas of tag 100. When tag 100 is to be tested, probe assembly 304 and/or tag 100 are moved so that the probes of probe assembly 304 make contact with the antenna(s) of tag 100, so that tag 100 can be tested.

Thus, test controller 302 includes software, hardware, and/or firmware, or any combination thereof, for testing functionality of tags. This incorporated software/hardware/firmware may be referred to as a “test module” included in test controller 302. Test controller 302 may be incorporated into a computer system. Test controller 302 can further include one or more storage devices for storing information regarding the test system and tags under test, including memory components, disc-based storage, magnetic storage devices, optical storage, etc. Furthermore, test controller 302 can include a user interface, such as including a keyboard, display, graphical user interface (GUI), pointing device, and/or other visual and/or audio indicators, for interacting with test controller 302 as needed.

The test module of test controller 302 generates one or more test signals to test tags. For example, test controller 302 may communicate with a tag under test according to any RFID communication protocol. The test controller 302 may generate the test signal(s) according to one or more interrogation/read protocols, as would be known to persons skilled in the relevant art(s), to read/communicate with tags under test. Example such protocols include binary protocols, tree traversal protocols, slotted aloha protocols, and those required by the following standards: Class 0; Class 1; and Gen 2. Any future developed communication algorithms/protocols are also within the scope and spirit of the present invention.

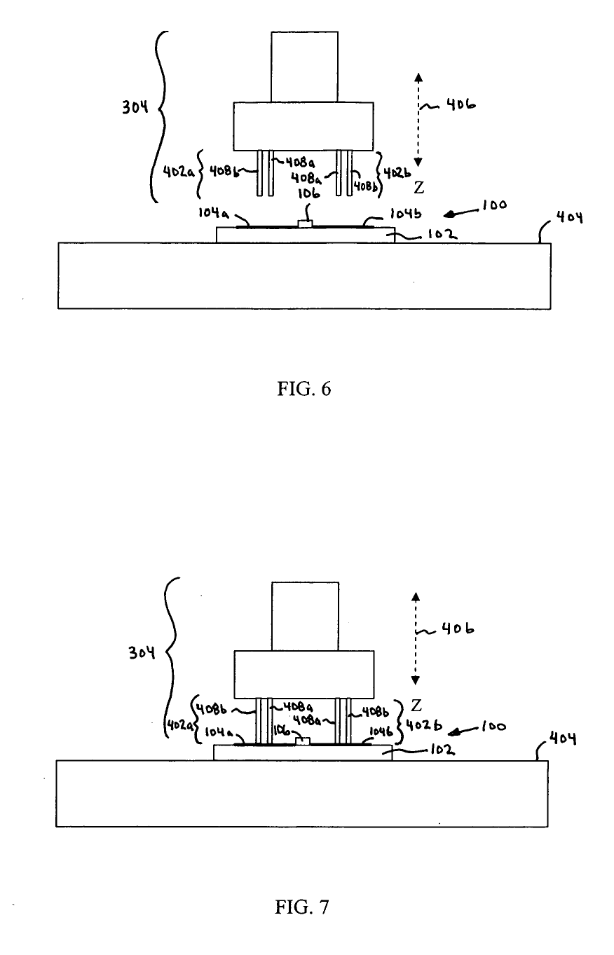

FIGS. 4 and 5 show views of probe assembly 304 interacting with tag 100 during a test, according to an example embodiment of the present invention. FIG. 4 shows probe assembly 304 positioned adjacent to tag 100. Tag 100 is supported by a surface 404. As shown in FIG. 4, probe assembly 304 includes a probe 402. A variety of configurations for probe 402 are applicable to embodiments of the present invention. In the embodiment of FIGS. 4 and 5, probe 402 includes a first probe element 408a and a second probe element 408b. First and second probe elements 408a and 408b can be any type of probe pair, as required by the particular application. For example, first and second probe elements 408a and 408b can be a pair of shielded RF probes. Probe 402 may include any number of one or more probe elements, as required by the particular application.

In the example of FIGS. 4 and 5, probe assembly 304 is capable of moving in the Z-direction, shown as Z-axis 406, which is a direction approximately orthogonal to a plane of tag 100.

In the example embodiment of FIGS. 4 and 5, when tag 100 is to be tested, probe assembly 304 is moved along a direction of Z-axis 406, in the direction of tag 100, so that probe 402 contacts antenna 104 as shown in FIG. 5. When probe 402 is in contact with antenna 104, test controller 302 (not shown in FIGS. 4 and 5) conducts test signal(s) through probe assembly 304 to probe 402, which applies the test signal(s) to antenna 104 of tag 100.

Tag 100 processes the received test signal(s), and generates a corresponding response. The response of tag 100 is conducted by antenna 104 to probe 402, which conducts the response through probe assembly 304 to test controller 302. Test controller 302 evaluates the response of tag 100.

Test signals can be provided through either of, or through both of first and second probe elements 408a and 408b. Furthermore, response signals can be received through either of, or through both of first and second probe elements 408a and 408b. In an example embodiment, test signals are provided through one of first and second probe elements 408a and 408b, and response signals are received through the other of first and second probe elements 408a and 408b. Furthermore, the ends of probes 408a and 408b that contact an antenna may be spaced apart by any amount, as required by the particular application.

Test controller 302 may evaluate the response of tag 100 to determine whether tag 100 is operating properly. For instance, the test signal(s) of test controller 302 may have interrogated tag 100 for its identification number. Test controller 302 evaluates whether tag 100 properly responded with its identification number. In further embodiments, data other than the identification number can be read from tag 100, to test other data, storage elements, and/or features of tag 100. In embodiments, any type of test may be performed, to test any feature, parameter, characteristic, etc., of tag 100.

If the identification number is properly received from tag 100 (and/or the tag otherwise responds properly), test controller 302 determines that tag 100 has passed the test, and test controller 302 proceeds accordingly. For example, in an embodiment, test controller 302 provides an indication that tag 100 passed the test by illuminating an indicator light, by displaying test result information on a graphical display, by storing test result information in storage, and/or by taking other action (or no action). If the identification number is improperly received (and/or the tag otherwise responds improperly), test controller 302 determines that tag 100 did not pass the test, and may not be functioning properly. For example, an improperly functioning tag may generate a response that is incorrect (i.e., is not the response expected from the tag for the particular test being performed, including a non-response). In such a situation, test controller 302 may provide an indication that tag 100 failed the test by marking tag 100 as defective, by illuminating an indicator light, by displaying test result information on a graphical display, by storing the test result information in storage, and/or by taking other action. In this manner, the failed tag 100 can subsequently be repaired, disposed, or recycled.

Note that probe assembly 304 may include a spring and/or other shock-absorption mechanism, to prevent damage to probe 402 and/or antenna 104 when they make contact.

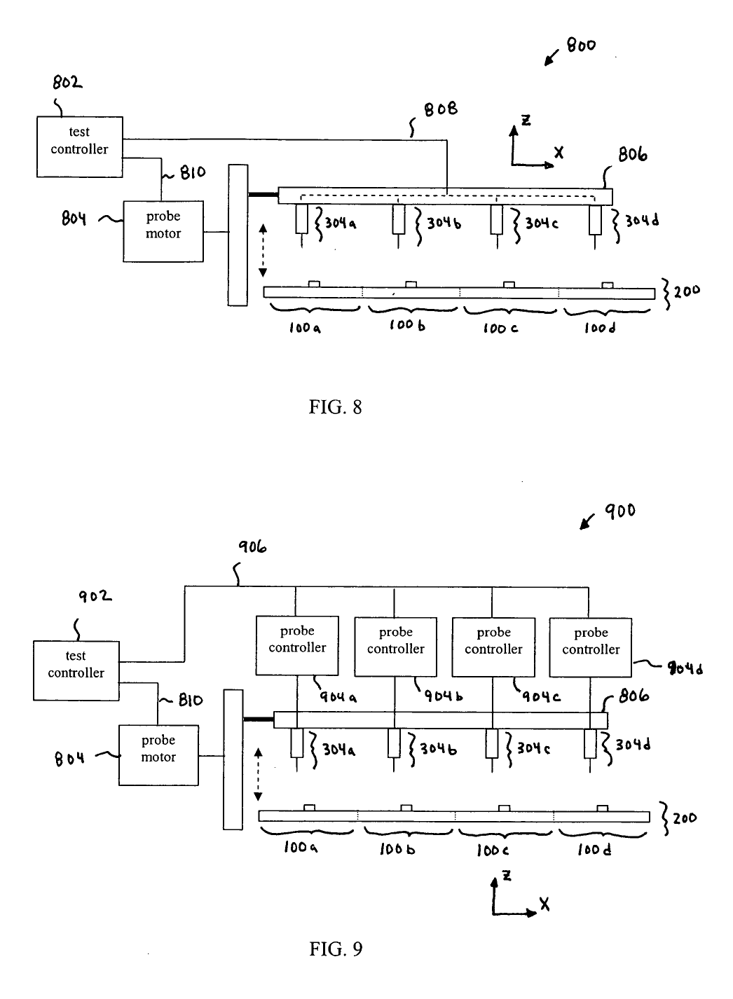

As shown in the example of FIGS. 4 and 5, probe assembly 304 may include a single probe 402. In further embodiments, probe assembly 304 may include multiple probes 402 for testing tag 100. For example, FIGS. 6 and 7 show a multi-probe embodiment for probe assembly 304, according to an embodiment of the present invention. As shown in FIGS. 6 and 7, probe assembly 304 includes first and second probes 402a and 402b. In FIGS. 6 and 7, tag 100 includes a first antenna 104a and a second antenna 104b. First and second antennas 104a and 104b may be electrically coupled together or electrically isolated from each other, depending on the particular tag type. In either case, in the present example embodiment, it is desired that first and second antennas 104a and 104b are tested separately. Thus, first probe 402a may be used to test first antenna 104a, and second probe 402a may be used to test second antenna 104b.

As shown in FIG. 7, probe assembly 304 has been moved so that first and second probes 402a and 402b are in contact with first and second antennas 104a and 104b, respectively. In this position, first and second probes 402a and 402b can supply test signals to first and second antennas 104a and 104b, respectively. Thus, the operation/functionality of tag 100 with respect to each of first and second antennas 104a and 104b can be tested.

Note that in embodiments, first and second probes 402a and 402b may be moved together or independently, to move in and out of contact with antennas 104a and 104b.

Multiple probes may be present as shown in FIGS. 6 and 7 for test of tag 100 for various reasons. For example, by using a probe to test each of antennas 104a and 104b, whether antennas 104a and 104b are properly coupled to die 106 can be verified. Furthermore, in an embodiment, tag 100 may include separate receiving channel circuits for first and second antennas 104a and 104b and/or separate transmitting channel circuits for each of first and second antennas 104a and 104b. By having separate tests conducted by separate probes, the receiving and transmitting channel circuits related to both of antennas 104a and 104b can be tested.

In an embodiment, first and second probes 402a and 402b perform the same test on their respective antennas. Alternatively, first and second probes 402a and 402b can perform different tests. In such an embodiment, the different test may be performed because the different antennas require different tests. In another embodiment, the different tests are performed on both antennas 104a and 104b. In such an embodiment, the different tests can be performed by running first and second test signals through each of first and second probes 402a and 402b, to conduct the respective tests. In another embodiment, the different tests can be performed by contacting first and second probes 402a and 402b to antennas 104a and 104b, respectively, and performing the first test, then “rotating” or otherwise switching first and second probes 402a and 402b with respect to antennas 104a and 104b, and performing the second test.

In embodiments, any number of tests can be performed. Furthermore, embodiments of the present invention are applicable to the testing of tags having any number of antennas, including one antenna, two antennas, three antennas, and further antennas.

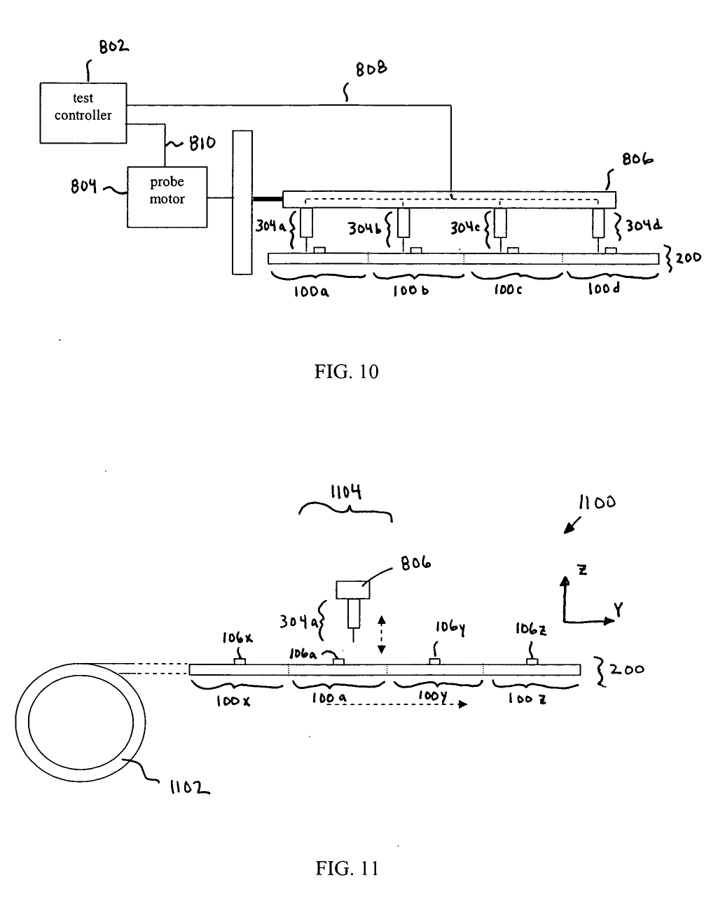

Furthermore, in embodiments, multiple tags may be tested in parallel using the direct connect scheme of the present invention. For example, FIG. 8 shows a multi-tag direct connect test system 800, according to an embodiment of the present invention. As shown in FIG. 8, test system 800 includes a test controller 802, a probe motor 804, and a probe mounting arm 806.

As further shown in FIG. 8, a plurality of probe assemblies 304a-304d are present in system 800. Probe assemblies 304a-304d are used to test tags 100a-100d, respectively, of web 200. Probe assemblies 304a-304d are mounted to probe mounting arm 806, which is a probe mount. A probe motor 804 is used to move probe mounting arm 806, causing probes of probe assemblies 304a-304d to move in and out of contact with antennas of tags 100a-100d as desired. For example, FIG. 10 shows probe mounting arm 806 having moved in a Z-direction towards web 200, to cause probes of probe assemblies 304a-304d to contact antennas of tags 100a-100d. Probe motor 804 can include any kind of movement/guide mechanism to move and guide probe mounting arm 806, as would be known by persons skilled in the relevant art(s). In an embodiment, one or more sensor devices, such as optical sensors, are present to monitor the positions of the probes with respect to tags 100a-100d, to make sure that precise contact with the antennas is made. Feedback from the sensors may be provided to probe motor 804 and/or test controller 802, to adjust the position of one or more of the probes as needed.

Test controller 802 performs similar functions to test controller 302 of FIG. 3 further described above. Test controller 302 is coupled through a first communications link 810 to probe motor 804. Test controller 802 provides control signals to control operation of probe motor 804 over first communications link 810, and may receive feedback from probe motor 804 over first communications link 810, if appropriate for a particular application.

Test controller 802 is coupled to probe assemblies 304a-304d through a second communications link 808, which may include a single communication link or multiple communication links. Test controller 802 is configured to provide test signals for each of probe assemblies 304a-304d through second communication link 808, and to receive responses from each of tags 100a-100d through second communications link 808. In this manner, test controller 802 can separately test each of tags 100a-100d.

FIG. 9 shows another example embodiment for a multi-tag direct connect test system 900. Test system 900 is generally similar to test system 800 shown in FIG. 8, with some differences described as follows. As shown in FIG. 9, test system 900 includes a plurality of probe controllers 904a-904d, each corresponding to one of probe assemblies 304a-304d. In the embodiment of test system 900, probe controllers 904a-904d each include the probe test functionality (e.g., “test module” described above) of a test controller. Thus, each of probe controllers 904a-904d can generate their own test signal(s) for providing to their respective one of tags 100a-100d under test, and can receive the respective test response signals. Probe controllers 904a-904d can process the test response signals and determine whether their respective one of tags 100a-100d under test has passed or failed its respective test. Each of probe controllers 904a-904d can then provide this information to test controller 902. In the embodiment of FIG. 9, test controller 902 coordinates the testing of tags 100a-100d by communicating with probe controllers 904a-904d, and by controlling probe motor 804.

Thus, for example, in the embodiment of FIG. 8, test controller 802 may be considered a “multi-channel” test controller, because it is capable of conducting testing with multiple probes simultaneously, while in the embodiment of FIG. 9, probe controllers 904a-904d may each be considered a “single-channel” test controller, when each of probe controllers 904a-904d is capable of conducting testing with a single probe. In further embodiments, a test system can include any combination of single-channel and multi-channel test controllers.

In embodiments, the test controllers described herein can include elements of conventional RFID readers. For example, depending on the particular application, a test controller may incorporate the power controls and read and write capabilities of an RFID reader, to control power output to the test probes, and to conduct the testing of tags. For instance, example conventional readers having features that are applicable to the embodiments of the present invention include AR400 and XR400 readers sold by Symbol Technologies of Holtsville, N.Y. The AR400 and XR400 are example 4-port readers that may be used in a “multi-channel” testing configuration, such as shown in FIG. 8.

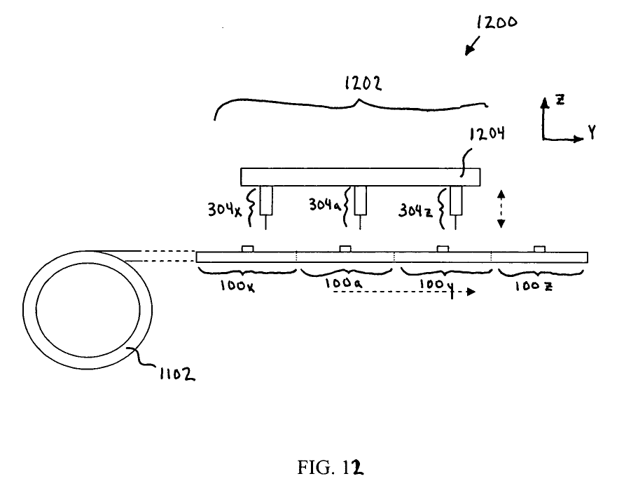

In embodiments, the systems described herein may be incorporated into a tag assembly line (TAL), which may be a partially or fully automated assembly line. For example, FIG. 11 shows a side view of a tag assembly line 1100 incorporating direct connect test functionality, according to an embodiment of the present invention. In the example of FIG. 11, tag assembly line 1100 receives a continuous roll 1102 of substrates, as web 200. Web 200 includes a plurality of substrates arranged in an array. Web 200 has a width in the X-direction (i.e., into the paper of FIG. 11) that is one or more substrates across. Web 200 has a length in the Y-direction that is substantially continuous (e.g., the length of a roll), and typically many substrates long. At one or more locations of tag assembly line 1100 (not shown in FIG. 11) prior to a tag testing station, dies 106 are applied to the substrates of web 200, and further tag assembly may occur, to produce tags 100 in web 200.

Once tags 100 have been assembled in web 200 to the extent that they are functional, they can be tested at a testing station 1104. Within testing station 1104, FIG. 11 shows probe mounting arm 806 positioned proximate to web 200, supporting probe assembly 304a over tag 100a. Probe mounting arm 806 may extend further in the X-direction to support additional probe assemblies 304 over tags 100 when web 200 has a width in the X-direction greater than a single tag. In such an embodiment, a row of tags 100 in web 200 may be tested in parallel, by moving probe mounting arm 806 towards web 200, to contact probes of multiple probe assemblies 304 to corresponding tags 100. After the test, probe mounting arm 806 can be withdrawn from the row of tags, web 200 can be advanced, and a next row of tags can be tested in a similar fashion. This process can continue until all the tags of web 200 have been tested.

Furthermore, in embodiments, arrays of tags may be tested in parallel. For example, FIG. 12 shows a side view of a tag assembly line 1200 incorporating direct connect test functionality for parallel test of an array of tags, according to an embodiment of the present invention. As shown in FIG. 12, in a testing station 1202, a probe mounting plate 1204 is present. Probe mounting plate 1204 is an example probe mount that mounts a plurality of probe assemblies 304, including a column of probe assemblies 304 in the Y-direction (i.e., 304x, 304a, and 304z), and a row of probe assemblies 304 in the X-direction (only first probe assembly in each row is shown in FIG. 12). Thus, for example, if probe mounting plate 1204 mounts a three by four array of probe assemblies 304, twelve tags 100 may be tested in parallel.

Once tags 100 are tested in web form, such as shown in FIGS. 11 and 12, further processing may be performed on the tested tags 100, including processing tags 100 into label format, singulation of web 200 into separate tags, removal of failed tags, etc.

Note that probe mounting arm 806 of FIG. 8 and probe mounting plate 1204 of FIG. 12 are types of probe mounts described for illustrative purposes, and that any type of probe mount may used, as would be understood by persons skilled in the relevant art(s), including individual mounts for each probe/probe assembly, etc.

As described above, embodiments of the present invention allow for faster and more reliable test of tags. Systems can be configured to test very large numbers of tags in parallel. For example, embodiments of the present invention can test both read-only and read/write tags at rates of greater than 5,000 tags an hour, including much greater rates, with near 100% repeatability. This is much faster than conventional systems which are typically capable of testing no more than 1,400 read/write tags per hour, with an approximately 95% repeatability rate.

In embodiments, the power level provided for test can be adjusted as required by the particular application, typically requiring much less power than radiated test signal schemes. Furthermore, the probes/probe assemblies can be impedance matched with the targeted tags, as would be understood by persons skilled in the relevant art(s). Initialization, read and write functions can be accomplished by test controllers quickly and reliably. Because the required power in a direct connect test scheme is smaller (e.g., hundreds of times less) than required by radiated test signal methods, there is little to no chance for adjacent tags to undesirably be read. Also, because each tag under test is probed directly and separately, identifying/locating a failed tag can be accomplished easily and accurately.

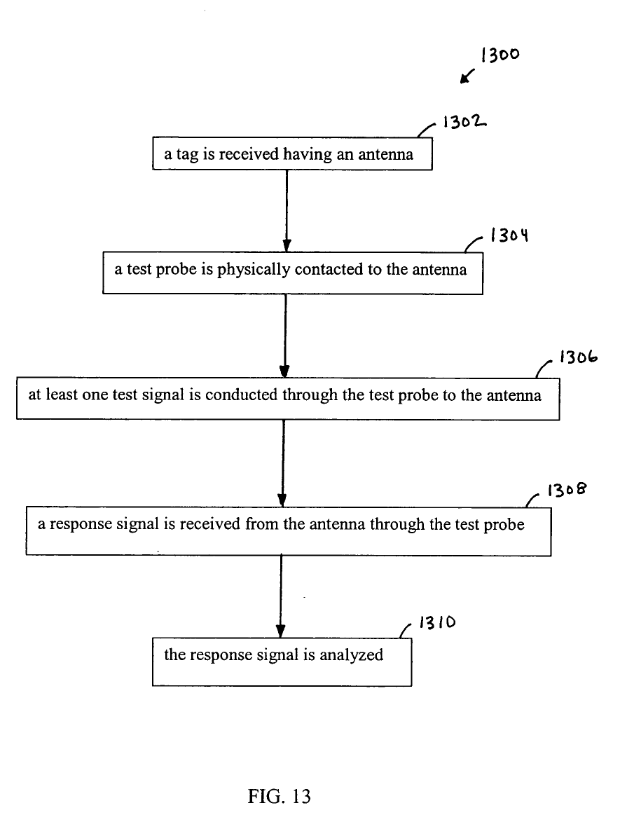

FIG. 13 shows a flowchart 1300 providing example steps for testing tags, according to an example embodiment of the present invention. Other structural and operational embodiments will be apparent to persons skilled in the relevant art(s) based on the following discussion related to flowchart 1300. The steps shown in FIG. 13 do not necessarily have to occur in the order shown. The steps of FIG. 13 are described in detail below.

Flowchart 1300 begins with step 1302. In step 1302, a tag is received having an antenna. For example, the tag is tag 100 shown in FIG. 1. As shown in FIG. 1, tag 100 has an antenna 104 formed on substrate 102.

In step 1304, a test probe is physically contacted to the antenna. For example, the test probe may be test probe 402 shown in FIG. 4. As shown in FIG. 5, first and second probe elements 408a and 408b of probe 402 are moved into physical contact with antenna 104.

In step 1306, at least one test signal is conducted through the test probe to the antenna. As described above, a test signal may be generated to test the tag. For example, a test controller may generate the test signal. In such an embodiment, the test controller is coupled to the test probe. The test probe conducts the test signal from the test controller to the tag antenna. In a two-element embodiment for probe 402, such as shown in FIGS. 4 and 5, the test signal may be conducted through either or both of probe elements 408a and 408b.

In step 1308, a response signal is received from the antenna through the test probe. As described above, a tag under test may generate a response. An improperly operating tag may generate a response that is incorrect (i.e., is not the response expected from the tag for the particular test being performed, including a non-response). In a two-element embodiment for probe 402, such as shown in FIGS. 4 and 5, the response signal may be received through either or both of probe elements 408a and 408b.

In step 1310, the response signal is analyzed. For example, the response signal may be analyzed by a test controller or other device, such as test controller 302 of FIG. 3, test controller 802 of FIG. 8, or probe controller 902 of FIG. 9. The response signal may be analyzed to determine whether the tag under test passed or failed the test, as described above. For example, if the response is a non-response, or is not expected data, the tag is determined to have failed the test.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method for testing radio frequency identification (RFID) tags, comprising:
(a) receiving a tag having an antenna formed on a substrate, and an integrated circuit on the substrate electrically coupled to the antenna;
(b) physically contacting a test probe to the antenna;
(c) conducting at least one test signal through the test probe to the antenna;
(d) receiving a response signal from the antenna through the test probe, the response signal being generated by the integrated circuit; and
(e) analyzing the response signal.

2. The method of claim 1, wherein step (a) comprises:
(1) receiving a plurality of tags that each have an antenna formed on a substrate, and an integrated circuit on the substrate electrically coupled to the antenna, the plurality of tags including the tag.

3. The method of claim 2, wherein step (b) comprises:
physically contacting a corresponding test probe to each antenna of the plurality of tags.

4. The method of claim 3, wherein step (c) comprises:
conducting at least one test signal through the corresponding test probe physically contacted to each antenna.

5. The method of claim 4, wherein step (d) comprises:
receiving a response signal from each antenna through the corresponding test probe.

6. The method of claim 5, wherein step (e) comprises:
analyzing the response signal received from each antenna.

7. The method of claim 2, wherein step (1) comprises:
receiving the plurality of tags in a web.

8. The method of claim 1, wherein step (e) comprises:
analyzing the response signal to determine whether the tag passed a test corresponding to the at least one test signal.

9. The method of claim 8, further comprising:
(f) disposing, marking, or recycling the tag if it is determined during step (e) that the tag failed the test.

10. The method of claim 1, wherein said probe is attached to a probe mount, wherein step (b) comprises:
moving the probe mount to move the probe into physical contact with the antenna.

11. The method of claim 10, wherein step (b) further comprises:
providing a control signal to a motor to move the probe mount.

12. The method of claim 1, wherein the test probe includes a first probe element and a second probe element, wherein step (c) includes:
conducting the at least one test signal through the first probe element to the antenna.

13. The method of claim 12, wherein step (d) comprises:
receiving the response signal from the antenna through the second probe element.

14. A system for testing radio frequency identification (RFID) tags, comprising:
a probe assembly that includes a probe; and
a test controller electrically coupled to said probe assembly;
wherein said probe is physically contacted to an antenna of a tag, and conducts at least one test signal to the antenna;
wherein a response signal from the antenna is received through the probe;
wherein the test controller analyzes the response signal.

15. The system of claim 14, wherein said probe assembly includes a second probe;
wherein said second probe is physically contacted to a second antenna of the tag, and conducts at least one test signal to the second antenna;
wherein a second response signal from the second antenna is received through the second probe;
wherein the test controller analyzes the second response signal.

16. The system of claim 14, wherein said probe comprises a first probe element and a second probe element.

17. The system of claim 16, wherein said at least one test signal is conducted to the antenna through said first probe element, and said response signal is received through said second probe element.

18. A system for testing a plurality of radio frequency identification (RFID) tags, comprising:
a plurality of probe assemblies that each include a probe; and
a test controller electrically coupled to each of said plurality of probe assemblies;
wherein said probe of each of said plurality of probe assemblies is physically contacted to a corresponding antenna of a respective tag, and conducts at least one test signal from said test controller to the corresponding antenna;
wherein a response signal is received through said probe of each of said plurality of probe assemblies from the corresponding antenna; and
wherein said test controller analyzes the response signal received through said probe of each of said plurality of probe assemblies.

19. The system of claim 18, wherein each of said probe assemblies includes a second probe;
wherein said second probe of said each of said probe assemblies is physically contacted to a second antenna of the respective tag, and conducts at least one test signal to the second antenna;
wherein a second response signal from the second antenna is received through said second probe of each of said plurality of probe assemblies; and
wherein the test controller analyzes the second response signal received through said second probe of each of said plurality of probe assemblies.

20. The system of claim 18, wherein said plurality of tags are received in a web format.

21. The system of claim 18, wherein said test controller analyzes said response signal received through said probe of each of said plurality of probe assemblies to determine whether the respective tag passed a test corresponding to the at least one test signal.

22. The system of claim 21, wherein a tag that is determined to have failed said test is disposed, marked, or recycled.

23. The system of claim 18, further comprising:
a probe mount that attaches said plurality of probe assemblies.

24. The system of claim 23, further comprising:
a probe motor coupled to said probe mount that is configured to move the probe mount to move the plurality of probe assemblies so that each probe makes physical contact with the corresponding antenna.

25. The system of claim 24, wherein said test controller generates a motor position control signal, wherein the probe motor receives the control signal.

26. The system of claim 23, wherein said probe mount attaches said plurality of probe assemblies in a row of probe assemblies.

27. The system of claim 23, wherein said probe mount attaches said plurality of probe assemblies in an array of probe assemblies.

28. The system of claim 18, wherein said test controller comprises a test module that includes a tag test algorithm.

29. A system for testing a plurality of radio frequency identification (RFID) tags, comprising:
a plurality of probe assemblies that each include a probe; and
a plurality of test controllers, wherein each test controller is electrically coupled to a corresponding one of said plurality of probe assemblies, wherein each test controller generates a respective at least one test signal;
wherein said probe of each of said plurality of probe assemblies is physically contacted to a corresponding antenna of a respective tag, and conducts said respective at least one test signal to the corresponding antenna;
wherein a response signal is received through said probe of each of said plurality of probe assemblies from the corresponding antenna; and
wherein each test controller analyzes the response signal received through said probe of said corresponding one of said plurality of probe assemblies.

30. A method for testing radio frequency identification (RFID) tags, comprising:
(a) receiving a tag having an antenna formed on a substrate;
(b) physically contacting a test probe to the antenna; and
(c) conducting a test of the tag through the test probe.
